(19) United States
(12) Patent Application Publication
(10) Pub. No.: US 2003/0030474 A1
(43) Pub. Date: Feb. 13, 2003

(54) Master-slave flip-flop with non-skewed complementary outputs, and methods to operate and manufacture the same

(76) Inventor: David McGowan, Blarney (IE)

Correspondence Address: BLAKELY, SOKOLOFF, TAYLOR & ZAFMAN LLP, Seventh Floor, 12400 Wilshire Boulevard, Los Angeles, CA, 90025-1026, US

(21) Appl. No.: 09/927,332

(22) Filed: Aug. 10, 2001

(51) Int. Cl. H03K 3/289

(52) U.S. Cl. 327/202

(57) ABSTRACT

A master-slave flip-flop includes a master section to receive an input signal, and first and second slave sections coupled to the master section. The first and second slave sections output respective true and complementary output signals. The first and second slave sections are furthermore identical, and coupled to common clock signals so that respective the first and second slave sections latch inputs from the master section simultaneously. In this way, the true and complementary output signals of the master-slave flip-flop are non-skewed relative to each other.

### FIELD OF THE INVENTION

The present invention relates to the field of electrical circuits and, in particular, to a master-slave flip-flop circuit.

### BACKGROUND

FIG. 1 is a schematic diagram illustrating the structure of a prior art positive-edge triggered master-slave flip-flop 10. The flip-flop 10 is operationally coupled to receive a single-ended input signal (D) 12 during a first state (or phase) of a clock signal (CB), to latch the state of the input signal 12 on a transition of the clock signal (CB), and to output the latched state during a second state of the clock signal (CB) as a true output signal Q14 and a complementary output signal \overline{Q} 16.

Structurally, the prior art flip-flop 10 includes a master section 18 and a slave section 20 coupled in series. The master section 18 follows the state of the input signal (D) 12 during a first phase of the clock signal (CP), while a previous state of the master section 18 as latched by the slave section 10, is outputted as the true output signal Q14 together with a complementary output signal \overline{Q} 16. The master section 18 then latches the state of the input signal (D) 12 as the clock signal transitions to a second state and drives the true output signal Q14 and the complementary output signal \overline{Q} 16 via the slave section 20, which unlatches in the second state. During a subsequent transition back to the first state of the clock signal CP, the slave section 20 latches the state of the master section 18 and the master section 18 unlatches state of the input signal (D) 12. The slave section 20 then outputs the latched former state of the master section 18 as the true output signal Q14.

As will be noted FIG. 1, the transmission path of the complementary output signal \overline{Q} 16 within the slave section 20 includes an extra inverter when compared to the transmission path for the true output Q14. The presence of this extra inverter operationally results in an unbalanced clock-Q, clock-\overline{Q} delay in the transmission paths of the true output signal Q14 and complementary output signal \overline{Q} 16. In timing critical applications, this delay may reduce setup/hold margins in downstream logic.

### SUMMARY OF THE INVENTION

A master-slave flip-flop includes a master section to receive and latch an input signal. First and second slave sections are coupled to the master section, the first and second slave sections operating to output respective true and complementary output signals. The first and second slave sections are identical so that the true and complementary output signals are non-skewed relative to each other.

Other features of the present invention will be apparent from the accompanying drawings and from the detailed description that follows.

### BRIEF DESCRIPTION OF THE DRAWINGS

The present invention is illustrated by way of example and not limitation in the figures of the accompanying drawings, in which like references indicate similar elements and in which:

FIG. 1 is a schematic diagram illustrating a prior art positive-edge triggered master-slave flip-flop.

FIG. 2 is a schematic diagram illustrating a master-slave flip-flop, according to an exemplary embodiment of the present invention.

FIG. 3 is a timing diagram showing transient responses of true and complementary output signals of the positive-edge triggered flip-flop.

FIG. 4 is a block diagram illustrating a machine in the exemplary form of a computer system, including a machine-readable medium on which a description of the present invention may be stored.

### DETAILED DESCRIPTION

A master-slave flip-flop with non-skewed complementary outputs, and methods to operate and manufacture the same, are described. Although the present invention has been described with reference to specific exemplary embodiments, it will be evident that various modifications and changes may be made to these embodiments without departing from the broader spirit and scope of the invention. Accordingly, the specification and drawings are to be regarded in an illustrative rather than a restrictive sense.

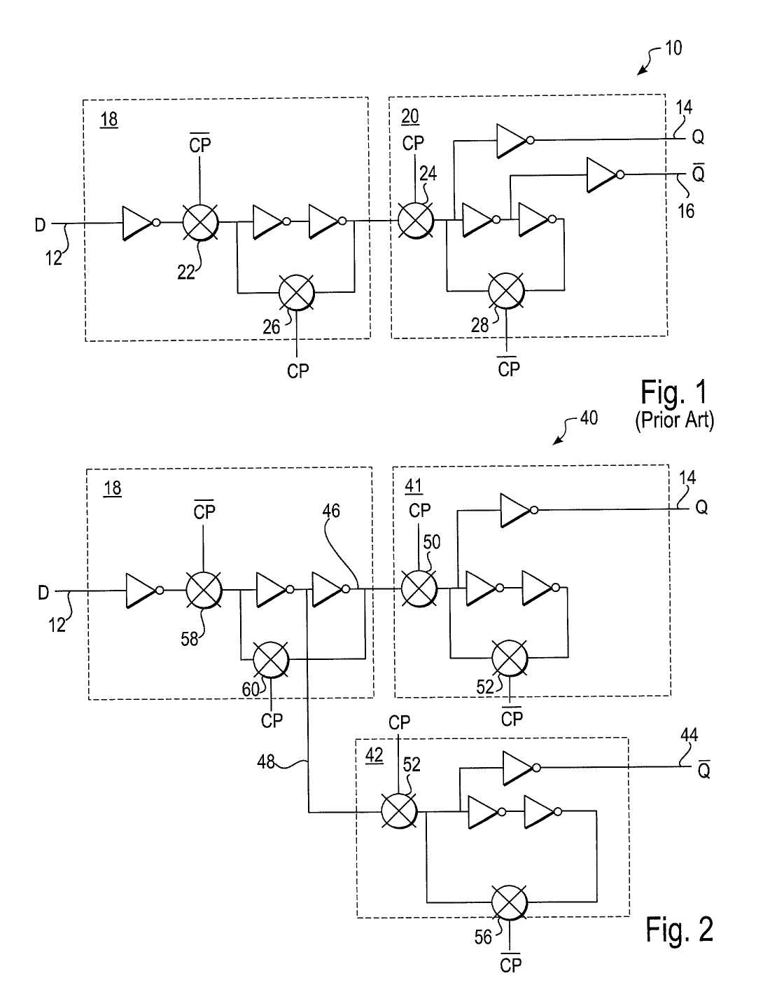

FIG. 2 is a schematic diagram illustrating a master-slave flip-flop 40 according to an exemplary embodiment to the present invention. While the exemplary flip-flop 40 is positive-edge triggered, the present invention is not limited to such a configuration and may be employed with a negative-edge triggered or an asynchronous set/reset flip-flop.

The exemplary flip-flop 40 is, as with the prior art flip-flop 10 shown in FIG. 1, coupled to receive a single-ended input signal (D) 12, and to output a true output signal 14 and a complementary output signal 44. As shown in FIG. 2, the flip-flop 40 includes a master section 18 that feeds two identical slave sections 41 and 42, which in turn output the true output signal 14 and the complementary output signal 44. The first and second slave sections 41 and 42 are furthermore coupled to receive complementary data outputs 46 and 48 from the master section 18, as illustrated. Dealing more specifically with the first and second slave sections 41 and 42, each includes a transmission (or pass) gate 50 or 52 that is coupled to receive a true (or normal) clock signal CP and a feedback gate 54 or 56 that is coupled to receive a complementary clock signal \overline{(CP)}. As the transmission gates 50 and 52 are operated by a common clock (e.g., true clock signal CP), input to the first and second slave sections 41 and 42 from the master section 18 will be registered on a common clock transition, and accordingly be propagated through the slave sections 41 and 42 in a simultaneous manner. As the first and second slave sections 41 and 42 are identical and clocked by a common clock, skew between the true output signal 14 and the complementary output signal 44 is reduced.

Operation of the flip-flop 40 will now be described with specific reference to the exemplary embodiment shown in FIG. 2. A person skilled in the art will of course appreciate that the operation of alternative embodiments (e.g., negative-edge triggered or asynchronous set/reset embodiments) will operate in a different manner. Nonetheless the principle of operation is to be understood to be extendable to these alternative embodiments.

Referring to FIG. 2, when the normal clock signal (CP) is driven low, the first and second slave sections 41 and 42 latch and maintain their previous (pre-clock transition) outputs, derived from the respective data outputs 46 and 48 from the master section 18. Specifically, the transmission gates 50 and 52 are closed when the normal clock signal (CP) is driven low, so as to isolate the first and second slave sections 41 and 42 from the data outputs 46 and 48 from the master section 18. The feedback gates 54 and 56, upon the normal clock signal (CP) being driven low, are opened so as to latch and maintain the outputs signals 14 and 44 that were extant at the normal clock transition.

The master section 18, upon the normal clock signal (CP) transitioning low, then assumes the same state as the input signal (D) 12 on account of the opening of a transmission gate 58 and a closing of the feedback gate 60.

Dealing now with operation when the normal clock (CP) transitions high, upon this clock transition the master section 18 latches the state of the input signal (D) 12, and the data outputs 46 and 48 from the master section 18 are propagated to the slave sections 41 and 42. Specifically, the respective transmission gates 50 and 52 are simultaneously opened upon the normal clock signal (CP) transitioning high, while the feedback gates 54 and 56 are closed. Again, it will be noted from FIG. 2 that the data outputs 46 and 48 from the master section 18 to the respective first and second slave sections 41 and 42 are complementary. Because the slave sections 41 and 42 are identical and are fed with the same clock signals, the true and complementary outputs signals 14 and 44 toggle at the same time on the normal clock (CP) positive edge.

When the normal clock (CP) again transitions low, the true and complementary output signals 14 and 44 are, as described above, latched in the same complementary state.

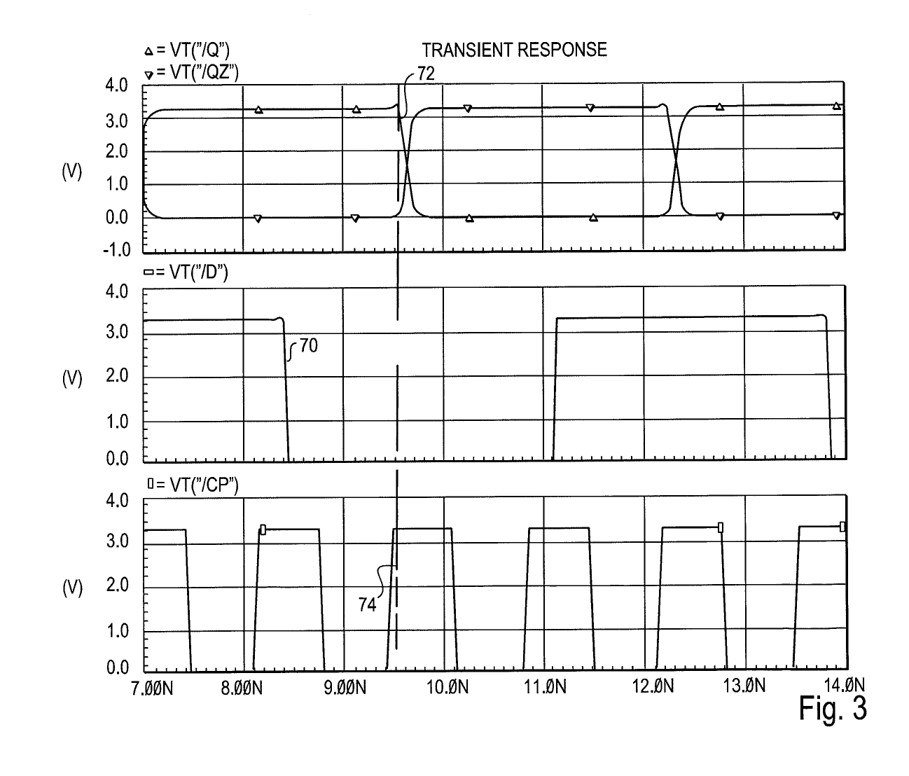

FIG. 3 illustrates exemplary timing diagrams showing the transient responses of the true and complementary output signals 14 and 44 of the positive-edge triggered flip-flop 40, responsive to transitions in the input signal (D) 12 and the normal clock signal (CP). In particular, it should be noted that a low transition of the input signal (D) 12, indicated in FIG. 3 at 70, is followed by the true output signal (Q) 14 at 72 responsive to a positive edge of the normal clock signal (CP) indicated at 74. It will also be noted from FIG. 3 that reduced skew between the responses of the true and complementary output signals 14 and 44 is exhibited.

The use of mirrored (or identical) slave sections 41 and 42 that are set (and reset) with the same clock signals within a master-slave flip-flop circuit addresses the problem of inverter skew between the true and complementary output signals 14 and 16 that is present in the prior art flip-flop 10, illustrated in FIG. 1. Furthermore, the present invention avoids the use of differential logic, which may not be feasible in certain applications as the use of differential logic may require a redesign of standard cells specific design. Accordingly, a master-slave flip-flop of the present invention may easily be added to a standard cell library both in schematic and layout form utilizing designed or laid out portions of existing cells. The present invention also provides a solution that is smaller than utilizing separate flip-flops to generate complementary outputs.

The present invention also extends to a method of manufacturing a master-slave flip-flop, whereby substantially identical slave sections 41 and 42 are coupled to receive complementary data inputs from a master section 18. An exemplary manner in which the substantially identical slave sections 41 and 42 may be coupled during a manufacturing process is indicated in FIG. 2. Furthermore, during the manufacturing process, the flip-flop may be manufactured in such a way such that the identical slave sections 41 and 42 may be operationally coupled to common clock signals, so that the slave sections 41 and 42 latch a pair of respective output signals from the master section 18 upon a common transition of the clock signal. Again, FIG. 2 illustrates an exemplary manner in which the slave sections 41 and 42 may be coupled and configured to operationally receive normal and complementary clock signals.

Note also that embodiments of the present description may be implemented not only within a physical circuit (e.g., on a semiconductor chip) but also within machine-readable media. For example, the circuits and designs discussed above may be stored upon and/or embedded within machine-readable media associated with a design tool used for designing semiconductor devices. Examples include a netlist formatted in the VHSIC Hardware Description Language (VHDL) language, Verilog language or SPICE language. Some netlist examples include: a behavioral level netlist, a register transfer level (RTL) netlist, a gate level netlist and a transistor level netlist. Machine-readable media also include media having layout information such as a GDS-II file. Furthermore, netlist files or other machine-readable media for semiconductor chip design may be used in a simulation environment to perform the methods of the teachings described above.

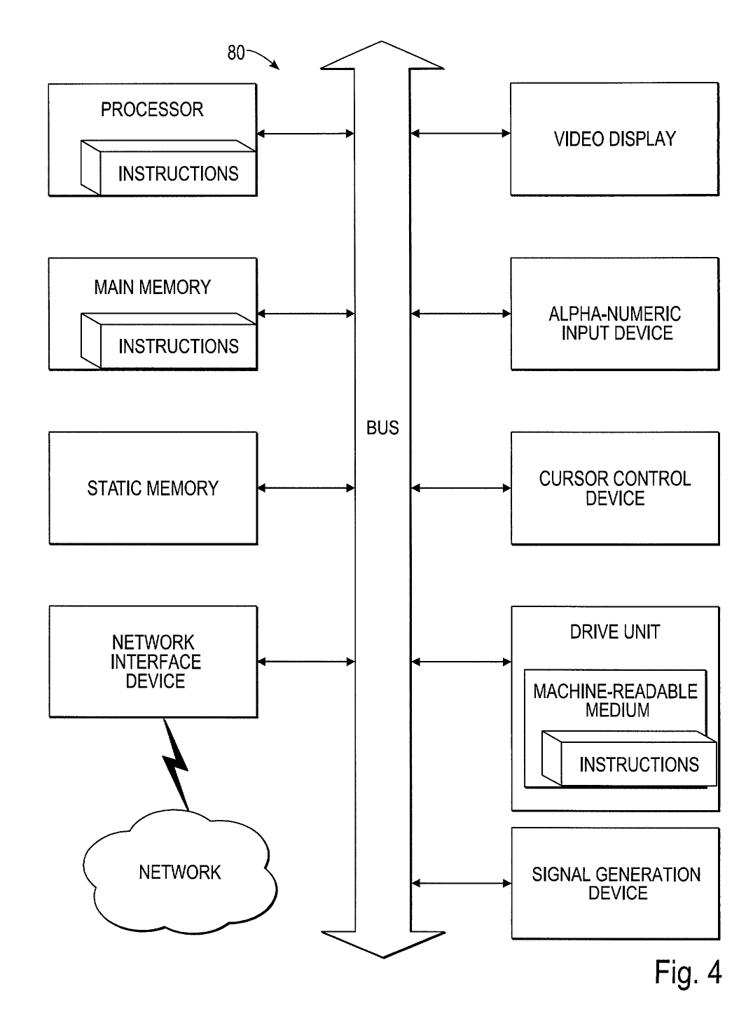

Thus, it is also to be understood that embodiments of this invention may be used as or to support a software program executed upon some form of processing core (such as the CPU of a computer) or otherwise implemented or realized upon or within a machine-readable medium. A machine-readable medium includes any mechanism for storing or transmitting information in a form readable by a machine (e.g., a computer). For example, a machine-readable medium includes read only memory (ROM); random access memory (RAM); magnetic disk storage media; optical storage media; flash memory devices; electrical, optical, acoustical or other form of propagated signals (e.g., carrier waves, infrared signals, digital signals, etc.); etc. FIG. 4 is a block diagram of a machine in the exemplary form of a computer system including a machine-readable medium on which a description of the present invention is stored.

Thus, a master-slave flip-flop with non-skewed complementary outputs, and methods of manufacturing and operating the same, have been described. Although the present invention has been described with reference to specific exemplary embodiments, it will be evident that various modifications and changes may be made to these embodiments without departing from the broader spirit and scope of the invention. Accordingly, the specification and drawings are to be regarded in an illustrative rather than a restrictive sense.

What is claimed is:

1. A master-slave flip-flop comprising:
a master section to receive and latch an input signal; and
first and second slave sections coupled to the master section, the first and second slave sections to output respective true and complementary output signals,
wherein the first and second slave sections are identical so that the true and complementary output signals are non-skewed relative to each other.

2. The master-slave flip-flop of claim 1 wherein the first and second slave sections are to receive and latch respective input signals received from the master section responsive to a common clock signal.

3. The master-slave flip-flop of claim 2 wherein the first slave section is coupled to receive a complementary master input signal from the master section, and the second slave section is coupled to receive a true master input signal from the master section, or vice versa.

4. The master-slave flip-flop of claim 1 where the first and second slave sections are each to receive both true and complementary clock signals.

5. The master-slave flip-flop of claim 4 wherein, when the true clock signal transitions from a first state to a second state, the first and second slave sections each latch a respective input signal received from the master section and the master section assumes a state of the input signal and, when the true clock signal transitions from the second to the first state, the state of the master section is assumed by the first slave section, a complementary state of the master section is assumed by the second slave section and the master section latches a state of the input signal.

6. The master-slave flip-flop of claim 1 wherein the flip-flop comprises any one of the group of flip-flop types including a positive-edge triggered flip-flop, a negative-edge triggered flip-flop and an asynchronous set/reset flip-flop.

7. The master-slave flip-flop of claim 1 wherein the flip-flop is to receive single-ended clock and data inputs.

8. A method of operating a master-slave flip-flop including a master section and first and second slave sections coupled to the master section, the first and second slave sections to output respective true and complementary output signals, the method including:
providing a true master input signal from the master section to the first slave section; providing a complementary master input signal from the master section to the section slave section; and
latching the complementary master input signal and the true master input signal at the first and section slave sections respectively responsive to a transition of a common clock signal;
wherein the first and second slave sections are identical so that the true and complementary output signals are non-skewed relative to each other.

9. The method of claim 8 including providing the common clock signal as both true and complementary clock signals to each of the first and second slave sections.

10. The method of claim 8 wherein, when the common clock signal transitions from a first state to a second state, the first and second slave sections each latch a respective complementary and true master input signal received from the master section and the master section assumes a state of the input signal and, when the common clock signal transitions from the second to the first state, the state of the master section is assumed by the first slave section, a complementary state of the master section is assumed by the second slave section and the master section latches a state of the input signal.

11. The method of claim 8 wherein the flip-flop comprises any one of the group of flip-flop types including a positive-edge triggered flip-flop, a negative-edge triggered flip-flop and an asynchronous set/reset flip-flop.

12. The method of claim 8 including providing single-ended clock and data inputs to the flip-flop.

13. A method of manufacturing a master-slave flip-flop including:
coupling first and second slave sections to a master section, to the master section operationally to receive and to latch an input signal and the first and second slave sections operationally to output respective true and complementary output signals,
wherein the first and second slave sections are identical so that the true and complementary output signals are operationally non-skewed relative to each other.

14. The method of claim 13 wherein the first and second slave sections are operationally to receive and latch respective input signals from the master section responsive to a common clock signal.

15. The method of claim 13 including coupling the first slave section to receive a complementary master input signal from the master section, and coupling the second slave section to receive a true master input signal from the master section, or vice versa.

16. A master-slave flip-flop comprising:
first means for receiving and latching an input signal; and
second and third means coupled to the first means, the second and third means for outputting respective true and complementary output signals,
wherein the second and third means are identical so that the true and complementary output signals are non-skewed relative to each other.

17. A machine-readable medium storing a description of a master-slave flip-flop circuit, said circuit comprising:
a master section to receive and latch an input signal; and
first and second slave sections coupled to the master section, the first and second slave sections to output respective true and complementary output signals,
wherein the first and second slave sections are identical so that the true and complementary output signals are non-skewed relative to each other.

18. The machine-readable medium of claim 17 wherein the description comprises a behavioral level description of the circuit.

19. The machine-readable medium of claim 18 wherein the behavioral level description is compatible with a VHDL format.

20. The machine-readable medium of claim 18 wherein the behavioral level description is compatible with a Verilog format.

21. The machine-readable medium of claim 17 wherein the description comprises a register transfer level netlist.

22. The machine-readable medium of claim 17 wherein the description comprises a transistor level netlist.
